(19) United States
(12) Patent Application Publication
(10) Pub. No.: US 2024/0114650 A1
(43) Pub. Date: Apr. 4, 2024

(54) SYSTEM AND METHOD FOR TARGETED COOLING IN A LIQUID COOLING SYSTEM

(71) Applicant: LENOVO ENTERPRISE SOLUTIONS (SINGAPORE) PTE LTD., Singapore (SG)

(72) Inventors: ARVIND MODEKURTI, MORRISVILLE, NC (US); VINOD KAMATH, RALEIGH, NC (US); JEFFREY S. HOLLAND, MORRISVILLE, NC (US)

(21) Appl. No.: 17/957,054

(22) Filed: Sep. 30, 2022

(51) Int. Cl. H05K 7/20; G06F 1/20; G06F 11/30

(52) U.S. Cl. CPC H05K 7/20272; G06F 1/206; G06F 11/3058; H05K 7/20281

(57) ABSTRACT

Targeted cooling in a liquid cooling system including detecting, for a node cooled by the liquid cooling system, a condition indicating increased heating, wherein the liquid cooling system includes a primary pump and a node-specific pump positioned in a loop of the liquid cooling system between the primary pump and the node; and responsive to detection of the condition, increasing cooling to the node by increasing liquid flow rate at the node-specific pump positioned in the loop of the liquid cooling system between the primary pump and the node, thereby achieving a higher temperature differential between an inlet and an outlet line and increased waste heat recovery.

### BACKGROUND

In current computing environments, servers or nodes are mounted in racks in a chassis. Servers generate a lot of heat. The server system is cooled using liquid such as water. Other computing systems such as personal computers also use liquid cooling. Cooling systems can be closed loop or open loop. Liquid cooling in the server chassis or personal computer or computing system uses a fixed flow rate to cool the system irrespective of workload or variation in generated heat or power usage in different areas. This results in wasted flow and a lower temperature differential between inlet and exhaust fluid. A higher temperature differential is preferred for high energy efficiency and increased waste heat recovery. Increasing the temperature differential with targeted flow control in liquid cooling is desired.

### SUMMARY

Methods, systems, and apparatus for targeted cooling in a liquid cooling system are disclosed in this specification. Targeted cooling in a liquid cooling system includes detecting, for a node cooled by the liquid cooling system, a condition indicating increased heating, wherein the liquid cooling system includes a primary pump and a node-specific pump positioned in a loop of the liquid cooling system between the primary pump and the node; and responsive to detection of the condition, increasing cooling to the node by increasing liquid flow rate at the node-specific pump positioned in the loop of the liquid cooling system between the primary pump and the node, thereby achieving a higher temperature differential between an inlet and an outlet line and increased waste heat recovery.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 sets forth a block diagram of an example system configured for targeted cooling in a liquid cooling system according to embodiments of the present disclosure.

FIG. 2 sets forth a block diagram of an example system configured for targeted cooling in a liquid cooling system according to embodiments of the present disclosure.

FIG. 3 sets forth a block diagram of an example system configured for targeted cooling in a liquid cooling system according to embodiments of the present disclosure.

FIG. 4 sets forth a flow chart illustrating an exemplary method for targeted cooling in a liquid cooling system according to embodiments of the present disclosure.

FIG. 5 sets forth a flow chart illustrating an exemplary method for targeted cooling in a liquid cooling system according to embodiments of the present disclosure.

FIG. 6 sets forth a flow chart illustrating an exemplary method for targeted cooling in a liquid cooling system according to embodiments of the present disclosure.

FIG. 7 sets forth a flow chart illustrating an exemplary method for targeted cooling in a liquid cooling system according to embodiments of the present disclosure.

FIG. 8 sets forth a flow chart illustrating an exemplary method for targeted cooling in a liquid cooling system according to embodiments of the present disclosure.

### DETAILED DESCRIPTION

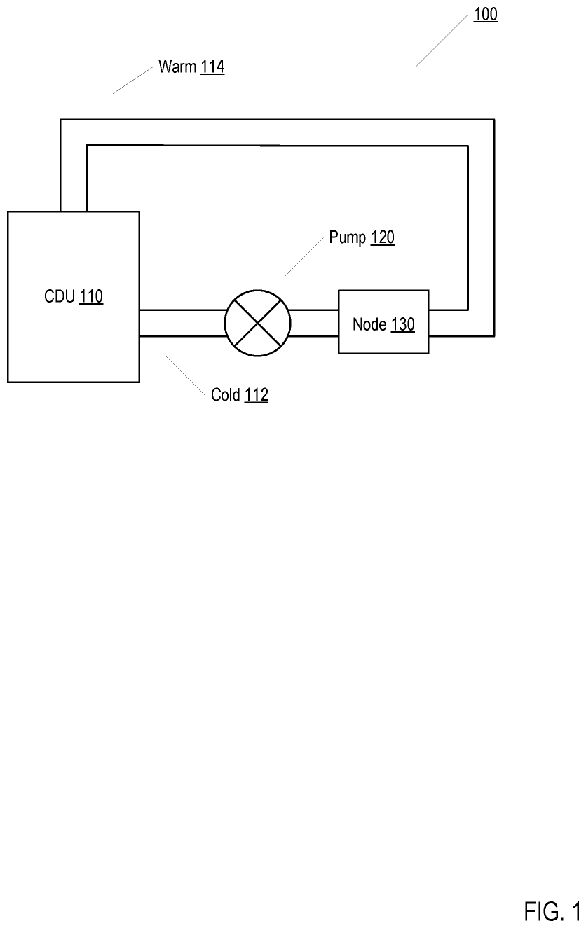

Exemplary methods, apparatus, and products for targeted cooling in a liquid cooling system in accordance with the present disclosure are described with reference to the accompanying drawings, beginning with FIG. 1. FIG. 1 sets forth a diagram of a cooling system 100 configured for targeted cooling in a liquid cooling system according to embodiments of the present disclosure. The cooling system 100 of FIG. 1 includes a coolant distribution unit (CDU) 110 which pumps cold or chilled liquid through the inlet loop 112 to pump 120 and to node 130 and receives warm liquid through the outlet or exhaust loop 114.

The cooling system 100 can be a closed loop or open loop system. The cooling liquid can be clean water or can be water or oil mixed with a solution such as propylene glycol or ethylene glycol or other additives including biocides and anti-corrosives.

The CDU 110 includes an internal pump and hardware and software that analyzes data and controls the internal pump as well as pump 120. The CDU 110 monitors the pressure and rate of flow of liquid in the loop and monitors the temperature differential of the inlet liquid and outlet liquid. The CDU 110 also receives information about node 130, including information about temperature from telemetry or about power usage or about workload at node 130. A more efficient cooling system has a greater temperature differential between the inlet and outlet or exhaust liquid. Additionally, a greater temperature differential permits greater waste heat recovery. Waste heat recovery can be used in building or water heating and overall energy and water efficiency.

The CDU 110 includes a heat exchanger that cools the liquid for the inlet loop 112. The heat exchanger may be a chiller and may be a water-to-water heat exchanger or water-to-air heat exchanger or other heat exchanger.

The pump 120 is a pump operable to increase liquid flow in a targeted manner for node 130. When node 130 uses more power or has a high workload or generates a higher temperature, pump 120 increases liquid flow and cooling specifically to node 130.

Node 130 is shown in FIG. 1. Node 130 may be one of many servers or nodes in a server system, such as a rack in a data center. Node 130 may be the only node in a personal computer, such as a central processing unit and a graphical processing unit, or the only node or one of several nodes in an edge computing device or other computing system.

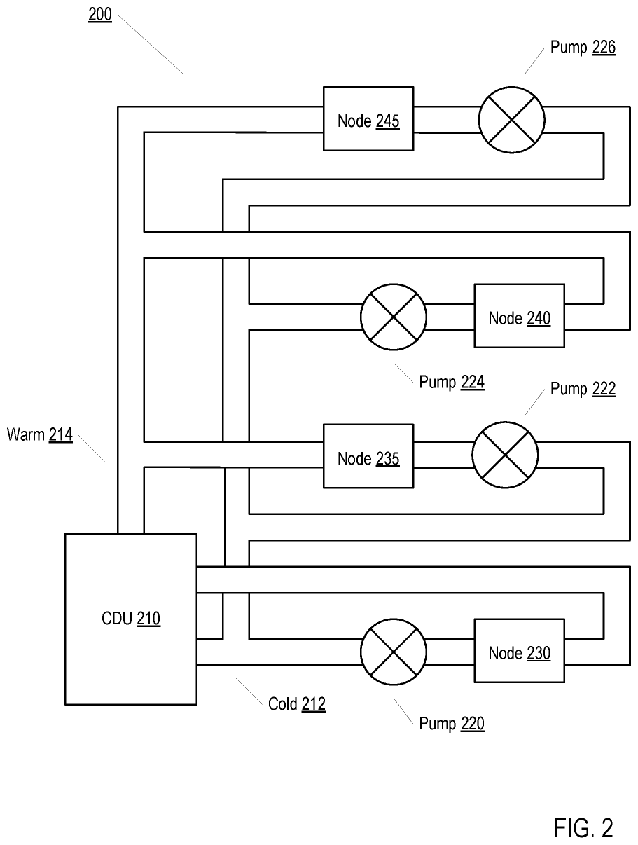

For further explanation, similar to FIG. 1, FIG. 2 sets forth a diagram of a cooling system 200 including an exemplary coolant distribution unit (CDU) 210 configured for targeted cooling in a liquid cooling system according to embodiments of the present disclosure. The coolant distribution unit (CDU) 210 pumps cold or chilled liquid through the inlet loops 212 to pump 220 and to node 230, to pump 222 and to node 235, to node 224 and to node 240, and to pump 226 and to node 245 and receives warm liquid through the outlet or exhaust loop 214. As in the cooling system 100 of FIG. 1, the cooling system 200 can be a closed loop or open loop system. The cooling liquid can be clean water or can be water or oil mixed with a solution such as propylene glycol or ethylene glycol or other additives including biocides and anti-corrosives.

In FIG. 2, the CDU 210 includes an internal pump and hardware and software that analyzes data and controls the internal pump as well as pump 120. The CDU 210 includes a heat exchanger that cools the liquid for the inlet loop 212. The heat exchanger may be a chiller and may be a water-to-water heat exchanger or water-to-air heat exchanger or other heat exchanger. The CDU 210 monitors the pressure and rate of flow of liquid and monitors the temperature differential of the inlet liquid and outlet liquid. The CDU 210 also receives information about nodes 230, 235, 240, and 245 including information about temperature from telemetry or about power usage or about workload at each node 230, 235, 240, and 245.

The pumps 220, 222, 224, and 226 are pumps operable to increase liquid flow in a targeted manner for nodes 230, 235, 240, and 245. When one of the nodes 230, 235, 240, and 245 uses more power, has a high workload, and generates a higher temperature, then the corresponding pump 220, 222, 224, or 226 increases liquid flow and cooling specifically to the node 230, 235, 240, or 245. Similarly, if two of the nodes 230, 235, 240, and 245 uses more power, has a high workload, and generates a higher temperature; or if three or more of the nodes 230, 235, 240, and 245 uses more power, has a high workload, and generates a higher temperature, then the corresponding pumps, then the corresponding pump 220, 222, 224, or 226 increases liquid flow and cooling specifically to the node 230, 235, 240, or 245.

Nodes 230, 235, 240, and 245 are shown in FIG. 2. Nodes 230, 235, 240, and 245 may be the entire server system or may be some of many servers or nodes in a server system, such as a rack in a data center, which may have hundreds or thousands of nodes. Each node 230, 235, 240, and 245 has a corresponding pump 220, 222, 224, and 226 to provide targeted liquid cooling as needed. While each node in FIG. 2 is shown having a corresponding pump, in an embodiment, there may be only one pump or some pumps but fewer that the total number of nodes to provide targeted cooling to some nodes in the system.

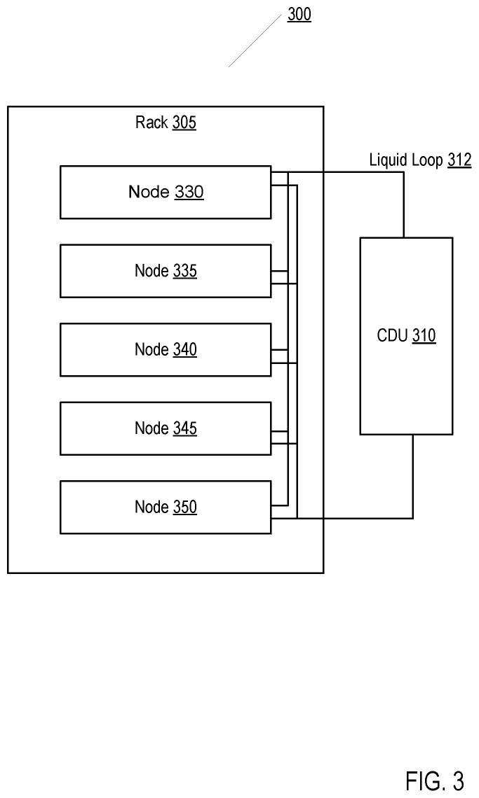

For further explanation, FIG. 3 sets forth a block diagram of computing machinery comprising an exemplary cooling system 300 configured for targeted cooling in a liquid cooling system according to embodiments of the present disclosure. The cooling system 300 of FIG. 3 includes CDU 310 and is housed in a rack 305 and manages cooling for nodes 330, 335, 340, 345, and 350 through liquid loop 312.

In FIG. 3, CDU 310 has a primary pump and can provide a flow rate of 1 to 3 liter per minute to up to 6 to 8 liters per minute of per node to fulfilling cooling requirements of a liquid cooled server. Nodes 330, 335, 340, 345, and 350 are computer servers that may include processors, memory, integrated network controllers, power supply, and storage drives in various configurations (not shown). Each node 330, 335, 340, 345, and 350 also includes a baseboard management controller that monitors the node including monitoring voltage and power consumption. Processors can use 500 to 1 kW per minute or more with heavy workloads. The CDU 310 monitors telemetry such as temperature sensors, voltage, or workload at nodes 330, 335, 340, 345, and 350. Each node 330, 335, 340, 345, and 350 uses cooling provided by CDU 310 in rack 305. Similar to the cooling systems 100 and 200 of FIGS. 1 and 2, pumps are located in liquid loop 312 for each of nodes 330, 335, 340, 345, and 350 in order to provide targeted increases in cooling. Each node 330, 335, 340, 345, and 350 may have its own node-specific pump or fewer than all nodes may have a node-specific pump.

In an exemplary embodiment, nodes 335 and 350 have heavy workloads while nodes 330, 340, and 345 are idle or have light workloads. Nodes 335 and 350 have a heavy power consumption and are generating more heat than nodes 330, 340, and 345. CDU 310 monitors the nodes and operates pumps associated with nodes 335 and 350 to target increased liquid flow and increased cooling for those nodes. Nodes 330, 340, and 345 are idle or have light workloads so receive normal cooling from CDU 310. Because nodes 335 and 350 are receiving additional liquid flow, the internal pump in CDU 310 may need adjustment to maintain steady liquid pressure and flow through the cooling system 300. It should be understood that a rack may include many servers or nodes and the nodes may be idle or have light or heavy workloads that may vary over time. CDU 310 adjusts liquid flow in a targeted way for each node so cooling can be targeted and efficient.

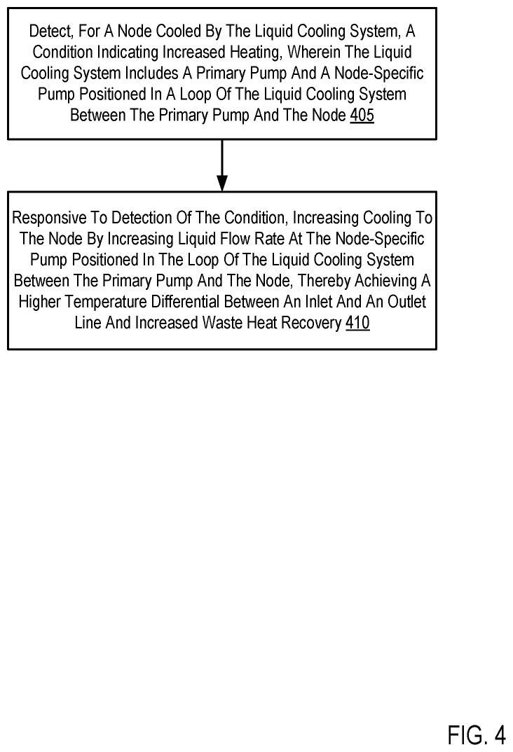

For further explanation, FIG. 4 sets forth a flow chart illustrating an exemplary method for targeted cooling in a liquid cooling system according to embodiments of the present disclosure that includes detecting (405), for a node cooled by the liquid cooling system, a condition indicating increased heating, wherein the liquid cooling system includes a primary pump and a node-specific pump positioned in a loop of the liquid cooling system between the primary pump and the node. Detecting (405), for a node cooled by the liquid cooling system, a condition indicating increased heating, wherein the liquid cooling system includes a primary pump and a node-specific pump positioned in a loop of the liquid cooling system between the primary pump and the node includes a liquid loop cooling system with a primary pump and a node-specific pump located in the liquid loop in a specific location for targeted cooling at the node. For example, pump 120 in FIG. 1 is a node-specific pump located in the liquid loop in a specific location for targeted increased liquid flow and cooling at its respective node 130 in FIG. 1. As described above, the liquid cooling system can be a closed loop or open loop system.

FIG. 4 also includes responsive to detection of the condition, increasing (410) cooling to the node by increasing liquid flow rate at the node-specific pump positioned in the loop of the liquid cooling system between the primary pump and the node, thereby achieving a higher temperature differential between an inlet and an outlet line and increased waste heat recovery. Responsive to detection of the condition, increasing (410) cooling to the node by increasing liquid flow rate at the node-specific pump positioned in the loop of the liquid cooling system between the primary pump and the node, thereby achieving a higher temperature differential between an inlet and an outlet line and increased waste heat recovery includes when a condition indicating increased heating is detected, increasing the flow rate at the node-specific pump in a specific location as controlled by the CDU. For example, CDU 110 in FIG. 1 operates pump 120 to increase liquid flow and cooling to node 130. Operating one or more pumps to target increased cooling to a specific location increases efficiency of the liquid loop cooling system and achieves a higher temperature differential between an inlet and an outlet line. Additionally, the higher temperature differential results in maximized waste heat recovery.

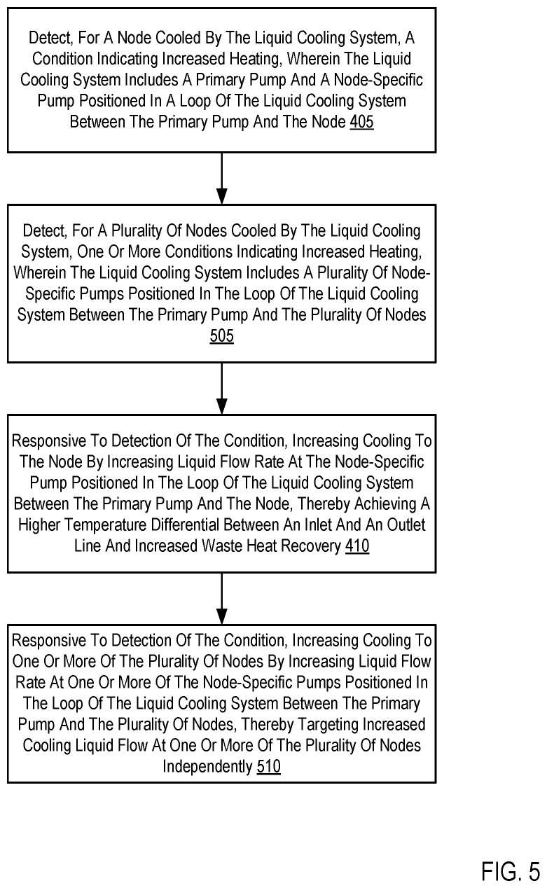

For further explanation, FIG. 5 sets forth a flow chart illustrating an exemplary method for targeted cooling in a liquid cooling system according to embodiments of the present disclosure. The method of FIG. 5 includes detecting (405), for a node cooled by the liquid cooling system, a condition indicating increased heating, wherein the liquid cooling system includes a primary pump and a node-specific pump positioned in a loop of the liquid cooling system between the primary pump and the node; and responsive to detection of the condition, increasing (410) cooling to the node by increasing liquid flow rate at the node-specific pump positioned in the loop of the liquid cooling system between the primary pump and the node, thereby achieving a higher temperature differential between an inlet and an outlet line and increased waste heat recovery.

The method of FIG. 5 differs from the method of FIG. 4, in that FIG. 5 further includes detecting (505), for a plurality of nodes cooled by the liquid cooling system, one or more conditions indicating increased heating, wherein the liquid cooling system includes a plurality of node-specific pumps positioned in the loop of the liquid cooling system between the primary pump and the plurality of nodes. Detecting (505), for a plurality of nodes cooled by the liquid cooling system, one or more conditions indicating increased heating, wherein the liquid cooling system includes a primary pump and a plurality of node-specific pumps positioned in the loop of the liquid cooling system between the primary pump and the plurality of nodes includes detecting a condition indicating increased heating at one node among many nodes or at several nodes or at all nodes. Additionally, the nodes have respective node-specific pumps for some or all nodes in the server system or other system. For example, pump 120 in FIG. 1 and pumps 220, 222, 224, and 226 in FIG. 2 are node-specific pumps located in the liquid loop in specific locations for targeted increased liquid flow and cooling at their respective nodes 130 in FIG. 1 and nodes 230, 235, 240, and 245 in FIG. 2.

FIG. 5 also includes responsive to detection of the condition, increasing (510) cooling to one or more of the plurality of nodes by increasing liquid flow rate at one or more of the node-specific pumps positioned in the loop of the liquid cooling system between the primary pump and the plurality of nodes, thereby targeting increased cooling liquid flow at one or more of the plurality of nodes independently. Responsive to detection of the condition, increasing (510) cooling to one or more of the plurality of nodes by increasing liquid flow rate at one or more of the node-specific pumps positioned in the loop of the liquid cooling system between the primary pump and the plurality of nodes, thereby targeting increased cooling liquid flow at one or more of the plurality of nodes independently includes when a condition indicating increased heating is detected at one or several or all nodes, increasing the flow rate at the node-specific pumps at specific locations as controlled by the CDU. For example, CDU 110 in FIG. 1 operates pump 120 to increase liquid flow and cooling to node 130; or, similarly, CDU 210 in FIG. 2 operates pump 220, 222, 224, 226 to increase liquid flow and cooling to node 230, 235, 240, or 245. Operating one or more pumps to target increased cooling to specific locations independently increases efficiency of the liquid loop cooling system and achieves a higher temperature differential between an inlet and an outlet line. Additionally, the higher temperature differential results in maximized waste heat recovery.

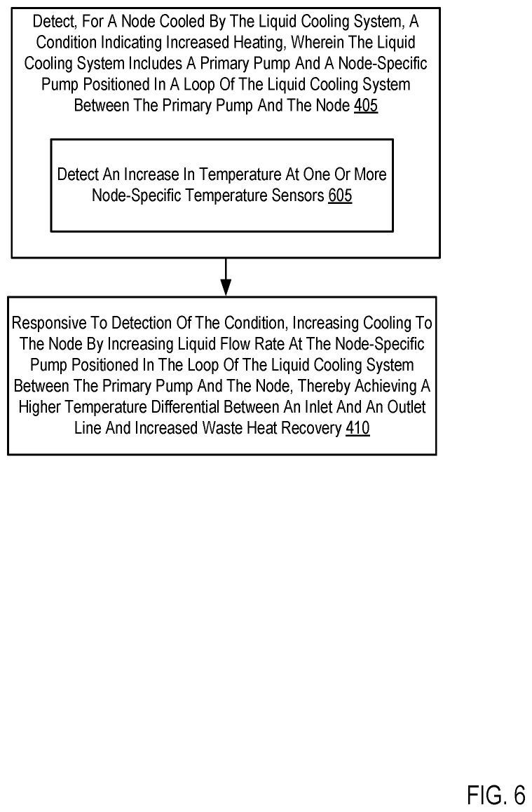

For further explanation, FIG. 6 sets forth a flow chart illustrating an exemplary method for targeted cooling in a liquid cooling system according to embodiments of the present disclosure. The method of FIG. 6 includes detecting (405), for a node cooled by the liquid cooling system, a condition indicating increased heating, wherein the liquid cooling system includes a primary pump and a node-specific pump positioned in a loop of the liquid cooling system between the primary pump and the node; and responsive to detection of the condition, increasing (410) cooling to the node by increasing liquid flow rate at the node-specific pump positioned in the loop of the liquid cooling system between the primary pump and the node, thereby achieving a higher temperature differential between an inlet and an outlet line and increased waste heat recovery.

The method of FIG. 6 differs from the method of FIG. 4, in that detecting (405), for a node cooled by the liquid cooling system, a condition indicating increased heating, wherein the liquid cooling system includes a primary pump and a node-specific pump positioned in a loop of the liquid cooling system between the primary pump and the node in FIG. 6 includes detecting (605) an increase in temperature at one or more node-specific temperature sensors. Detecting (605) an increase in temperature at one or more node-specific temperature sensors includes detecting when the temperature in a specific location rises. The CDU operates one or more node-specific pumps to increase liquid flow and to increase cooling in a specific location based upon telemetry information from one or more node-specific temperature sensors. For example, CDU 110 in FIG. 1 operates pump 120 to increase liquid flow and cooling to node 130; or, similarly, CDU 210 in FIG. 2 operates pump 220, 222, 224, 226 to increase liquid flow and cooling to node 230, 235, 240, or 245. More specifically, CDU 310 in FIG. 3 operates pumps for nodes 335 and 350 that have higher temperatures in order to increase liquid flow and cooling to those nodes.

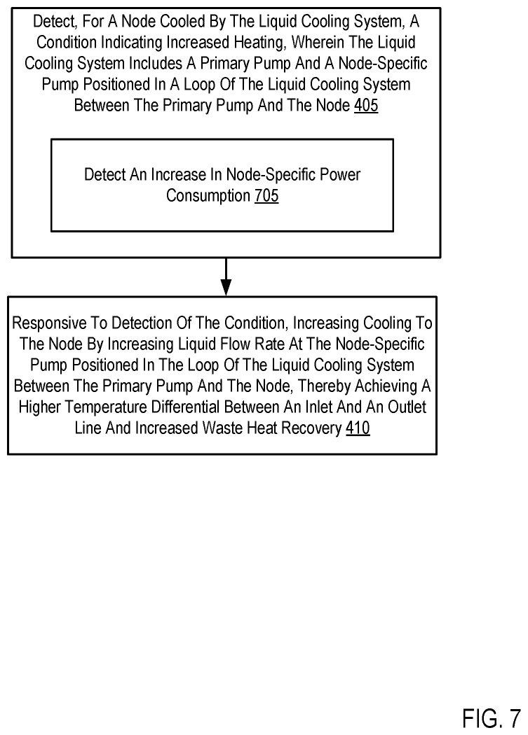

For further explanation, FIG. 7 sets forth a flow chart illustrating an exemplary method for targeted cooling in a liquid cooling system according to embodiments of the present disclosure. The method of FIG. 7 includes detecting (405), for a node cooled by the liquid cooling system, a condition indicating increased heating, wherein the liquid cooling system includes a primary pump and a node-specific pump positioned in a loop of the liquid cooling system between the primary pump and the node; and responsive to detection of the condition, increasing (410) cooling to the node by increasing liquid flow rate at the node-specific pump positioned in the loop of the liquid cooling system between the primary pump and the node, thereby achieving a higher temperature differential between an inlet and an outlet line and increased waste heat recovery.

The method of FIG. 7 differs from the method of FIG. 4, in that detecting (405), for a node cooled by the liquid cooling system, a condition indicating increased heating, wherein the liquid cooling system includes a primary pump and a node-specific pump positioned in a loop of the liquid cooling system between the primary pump and the node in FIG. 7 includes detecting (705) an increase in node-specific power consumption. Detecting (705) an increase in node-specific power consumption includes the CDU receiving information about power consumption at a specific node and operating one or more pumps to increase liquid flow and to increase cooling in the specific location based upon power usage information. When a specific location uses more power, then the CDU operates one or more pumps to increase cooling to the specific location.

The CDU may receive power information from the nodes or from a rack or from another monitoring source. For example, CDU 110 in FIG. 1 operates pump 120 to increase liquid flow and cooling to node 130; or, similarly, CDU 210 in FIG. 2 operates pump 220, 222, 224, 226 to increase liquid flow and cooling to node 230, 235, 240, or 245 based upon information from the nodes or from rack 305. More specifically, CDU 310 in FIG. 3 operates pumps for nodes 335 and 350 that have greater power consumption in order to increase liquid flow and cooling to those nodes.

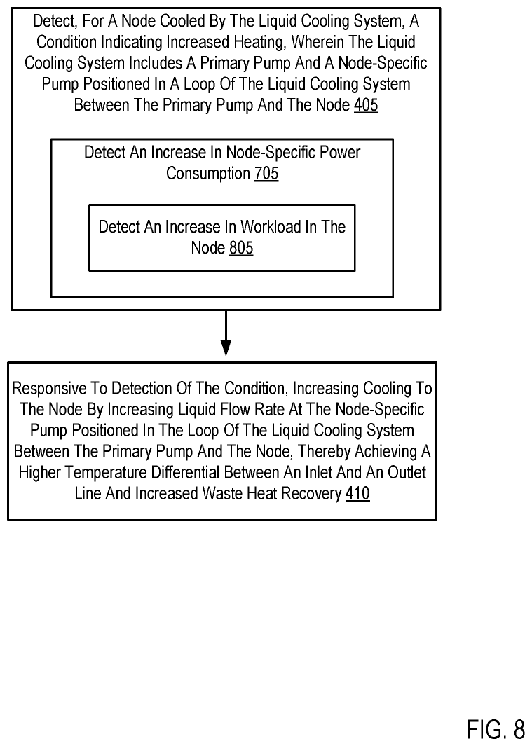

For further explanation, FIG. 8 sets forth a flow chart illustrating an exemplary method for targeted cooling in a liquid cooling system according to embodiments of the present disclosure. The method of FIG. 8 includes detecting (405), for a node cooled by the liquid cooling system, a condition indicating increased heating, wherein the liquid cooling system includes a primary pump and a node-specific pump positioned in a loop of the liquid cooling system between the primary pump and the node; and responsive to detection of the condition, increasing (410) cooling to the node by increasing liquid flow rate at the node-specific pump positioned in the loop of the liquid cooling system between the primary pump and the node, thereby achieving a higher temperature differential between an inlet and an outlet line and increased waste heat recovery.

The method of FIG. 8 differs from the method of FIG. 4, in that detecting (405), for a node cooled by the liquid cooling system, a condition indicating increased heating, wherein the liquid cooling system includes a primary pump and a node-specific pump positioned in a loop of the liquid cooling system between the primary pump and the node includes detecting (705) an increase in node-specific power consumption in FIG. 8 includes detecting (805) an increase in workload in the node. Detecting (805) an increase in workload in the node includes detecting more workloads at a specific node and the CDU operating one or more pumps to increase liquid flow and to increase cooling in the specific location based upon the workload information. When a specific location has a heavy workload, then the CDU operates one or more pumps to increase cooling to the specific location.

The CDU may receive workload information from the nodes or a controller or from another monitoring source. For example, CDU 110 in FIG. 1 operates pump 120 to increase liquid flow and cooling to node 130; or, similarly, CDU 210 in FIG. 2 operates pump 220, 222, 224, 226 to increase liquid flow and cooling to node 230, 235, 240, or 245 based upon information from the nodes or from a controller internal or external to rack 305. More specifically, CDU 310 in FIG. 3 operates pumps for nodes 335 and 350 that have heavy workloads in order to increase liquid flow and cooling to those nodes.

In view of the explanations set forth above, readers will recognize that the benefits of targeted cooling in a liquid cooling system according to embodiments of the present disclosure include:
Increased cooling capacity and efficiency
Increasing the temperature differential with targeted flow control in liquid cooling, thereby maximizing waste heat recovery

Exemplary embodiments of the present disclosure are described largely in the context of a fully functional computer system for targeted cooling in a liquid cooling system. Readers of skill in the art will recognize, however, that the present disclosure also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the disclosure as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present disclosure.

The present disclosure may be a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method for targeted cooling in a liquid cooling system, the method comprising:
detecting, for a node cooled by the liquid cooling system, a condition indicating increased heating, wherein the liquid cooling system includes a primary pump and a node-specific pump positioned in a loop of the liquid cooling system between the primary pump and the node; and
responsive to detection of the condition, increasing cooling to the node by increasing liquid flow rate at the node-specific pump positioned in the loop of the liquid cooling system between the primary pump and the node.

2. The method of claim 1 further comprising:
detecting, for a plurality of nodes cooled by the liquid cooling system, one or more conditions indicating increased heating, wherein the liquid cooling system includes a plurality of node-specific pumps positioned in the loop of the liquid cooling system between the primary pump and the plurality of nodes; and
responsive to detection of the one or more conditions, increasing cooling to one or more of the plurality of nodes by increasing liquid flow rate at one or more of the node-specific pumps positioned in the loop of the liquid cooling system between the primary pump and the plurality of nodes, thereby targeting increased cooling liquid flow at one or more of the plurality of nodes independently.

3. The method of claim 1 wherein detecting, for the node cooled by the liquid cooling system, the condition indicating increased heating comprises:
detecting an increase in temperature at one or more node-specific temperature sensors.

4. The method of claim 1 wherein detecting, for the node cooled by the liquid cooling system, the condition indicating increased heating comprises:
detecting an increase in node-specific power consumption.

5. The method of claim 4 wherein detecting an increase in node-specific power consumption comprises:
detecting an increase in workload in the node.

6. The method of claim 1 wherein the liquid loop cooling system is a closed loop system.

7. The method of claim 1 wherein the liquid loop cooling system is an open loop system.

8. An apparatus for targeted cooling in a liquid cooling system using a pump, the apparatus comprising a computer processor, a computer memory operatively coupled to the computer processor, the computer memory having disposed within it computer program instructions that, when executed by the computer processor, cause the apparatus to perform operations comprising:
detecting, for a node cooled by the liquid cooling system, a condition indicating increased heating, wherein the liquid cooling system includes a primary pump and a node-specific pump positioned in a loop of the liquid cooling system between the primary pump and the node; and
responsive to detection of the condition, increasing cooling to the node by increasing liquid flow rate at the node-specific pump positioned in the loop of the liquid cooling system between the primary pump and the node.

9. The apparatus of claim 8, the operations further comprising:
detecting, for a plurality of nodes cooled by the liquid cooling system, one or more conditions indicating increased heating, wherein the liquid cooling system includes a plurality of node-specific pumps positioned in the loop of the liquid cooling system between the primary pump and the plurality of nodes; and
responsive to detection of the one or more conditions, increasing cooling to one or more of the plurality of nodes by increasing liquid flow rate at one or more of the node-specific pumps positioned in the loop of the liquid cooling system between the primary pump and the plurality of nodes, thereby targeting increased cooling liquid flow at one or more of the plurality of nodes independently.

10. The apparatus of claim 8, wherein detecting, for the node cooled by the liquid cooling system, the condition indicating increased heating comprises:
detecting an increase in temperature at one or more node-specific temperature sensors.

11. The apparatus of claim 8, wherein detecting, for the node cooled by the liquid cooling system, the condition indicating increased heating comprises:
detecting an increase in node-specific power consumption.

12. The apparatus of claim 11 wherein detecting an increase in node-specific power consumption comprises:
detecting an increase in workload in the node.

13. The apparatus of claim 8 wherein the liquid loop cooling system is a closed loop system.

14. The apparatus of claim 8 wherein the liquid loop cooling system is an open loop system.

15. A computer program product for targeted cooling in a liquid cooling system using a pump, the computer program product comprising a computer readable medium storing computer program instructions that, when executed, cause a computer to perform operations comprising:
detecting, for a node cooled by the liquid cooling system, a condition indicating increased heating, wherein the liquid cooling system includes a primary pump and a node-specific pump positioned in a loop of the liquid cooling system between the primary pump and the node; and
responsive to detection of the condition, increasing cooling to the node by increasing liquid flow rate at the node-specific pump positioned in the loop of the liquid cooling system between the primary pump and the node.

16. The computer program product of claim 15, the operations further comprising:
detecting, for a plurality of nodes cooled by the liquid cooling system, one or more conditions indicating increased heating, wherein the liquid cooling system includes a plurality of node-specific pumps positioned in the loop of the liquid cooling system between the primary pump and the plurality of nodes; and
responsive to detection of the one or more conditions, increasing cooling to one or more of the plurality of nodes by increasing liquid flow rate at one or more of the node-specific pumps positioned in the loop of the liquid cooling system between the primary pump and the plurality of nodes, thereby targeting increased cooling liquid flow at one or more of the plurality of nodes independently.

17. The computer program product of claim 15, wherein detecting, for the node cooled by the liquid cooling system, the condition indicating increased heating comprises:
detecting an increase in temperature at one or more node-specific temperature sensors.

18. The computer program product of claim 15 wherein detecting, for the node cooled by the liquid cooling system, the condition indicating increased heating comprises:
detecting an increase in node-specific power consumption.

19. The computer program product of claim 18 wherein detecting an increase in node-specific power consumption comprises:
detecting an increase in workload in the node.

20. The computer program product of claim 15 wherein the computer readable medium comprises a storage medium.
